(19) United States
(12) Patent Application Publication
(10) Pub. No.: US 2026/0293449 A1
(43) Pub. Date: Sep. 24, 2026

(54) DISPLAY PANEL, MANUFACTURING METHOD THEREOF, AND ELECTRONIC DEVICE

(71) Applicant: WUHAN TIANMA MICROELECTRONICS CO., LTD. SHANGHAI BRANCH, Shanghai (CN)

(72) Inventors: Yu XIN, Shanghai (CN); Peng ZHANG, Shanghai (CN); Xian CHEN, Shanghai (CN); Jingjing HUANG, Shanghai (CN)

(73) Assignee: WUHAN TIANMA MICROELECTRONICS CO., LTD. SHANGHAI BRANCH, Shanghai (CN)

(21) Appl. No.: 19/687,106

(22) Filed: May 26, 2026

(30) Foreign Application Priority Data
Jan. 14, 2026 (CN) 202610050910.3

(51) Int. Cl. H10K 59/122; H10K 59/12; H10K 59/80

(52) U.S. Cl. CPC H10K 59/122; H10K 59/1201; H10K 59/80515

(57) ABSTRACT

A display panel includes: a base substrate; an anode metal layer disposed on a surface of the base substrate and including multiple anodes; a pixel definition layer disposed on a surface of the anode metal layer facing away from the base substrate. The pixel definition layer includes: multiple pixel openings corresponding to the anodes; multiple first protrusions disposed on a surface of the pixel definition layer facing away from the base substrate, each of the first protrusions being located between two adjacent pixel openings in a first direction, the first direction being parallel to a plane where the base substrate is located. The first protrusion has a first orthogonal projection on the plane where the base substrate is located, and the pixel opening has a second orthogonal projection on the plane. In the first direction, the first orthogonal projection is parallel to two adjacent second orthogonal projections.

This application claims priority to Chinese Patent Application No. 202610050910.3, filed on Jan. 14, 2026, which is hereby incorporated by reference in its entirety.

### FIELD

The present application relates to the field of display panels, and in particular, to a display panel, a manufacturing method of a display panel, and an electronic device.

### BACKGROUND

Organic Light-Emitting Diode (OLED) display panels have become one of the mainstream display panels, due to numerous advantages such as high brightness, high contrast ratio, wide color gamut, bendability, low-temperature resistance, low power consumption, and high luminous efficiency. During the manufacturing process of the OLED panel, a Fine Metal Mask (FMM) evaporation process is required to fabricate the light-emitting layer of a light-emitting element. In a conventional display panel, multiple Point-Supporting (PS) pillars need to be separately formed on a surface of a pixel definition layer to support the fine metal mask, to prevent the fine metal mask from directly contacting the pixel definition layer, thereby reducing problems such as scratches on the inner film layer of the display panel and abrasion of the fine metal mask caused by friction.

In the conventional technology, the point-supporting pillars need to be manufactured separately on the pixel definition layer by an additional coating and photolithography process, which increases the manufacturing process complexity and manufacturing cost of the display panel.

### SUMMARY

In view of the above problems, a display panel, a manufacturing method of a display panel, and an electronic device are provided according to the present disclosure. The specific solutions are as follows.

In an embodiment of the present application, a display panel is provided. The display panel includes: a base substrate; an anode metal layer disposed on a surface of the base substrate and including multiple anodes; a pixel definition layer disposed on a surface of the anode metal layer facing away from the base substrate.

The pixel definition layer includes: multiple pixel openings corresponding to the anodes, where at least part of an anode of the anodes is exposed through a pixel opening corresponding to the anode; multiple first protrusions disposed on a surface of the pixel definition layer facing away from the base substrate, where each of the first protrusions is located between two adjacent pixel openings in a first direction, and the first direction is parallel to a plane where the base substrate is located. Each of the first protrusions has a first orthogonal projection on the plane where the base substrate is located, and each of the pixel openings has a second orthogonal projection on the plane; in the first direction, the first orthogonal projection is parallel to two adjacent second orthogonal projections.

In an embodiment of the present disclosure, an electronic device is provided. The electronic device includes the display panel as described above.

In an embodiment of the present disclosure, a manufacturing method of the above display panel is provided. The method includes: providing a base substrate; forming a patterned anode metal layer on a surface of the base substrate, the anode metal layer including multiple anodes; forming an initial pixel definition layer on the surface of the base substrate on which the anodes are formed; forming a pixel definition layer with a desired pattern structure in the initial pixel definition layer by using a half-tone mask. The pixel definition layer includes: multiple pixel openings in one-to-one correspondence with the anodes, and at least part of an anode of the anodes is exposed through a pixel opening corresponding to the anode; multiple first protrusions disposed on a surface of the pixel definition layer facing away from the base substrate, where each of the first protrusions is located between two adjacent pixel openings in a first direction, and the first direction is parallel to a plane where the base substrate is located. Each of the first protrusions has a first orthogonal projection on the plane where the base substrate is located, and each of the pixel openings has a second orthogonal projection on the plane; and in the first direction, the first orthogonal projection is parallel to two adjacent second orthogonal projections.

### BRIEF DESCRIPTION OF THE DRAWINGS

To more clearly illustrate the embodiments of the present application, the drawings used in the description of the embodiments or the conventional art will be briefly introduced below.

The structures, proportions, sizes and the like shown in the accompanying drawings of this specification are only used to cooperate with the content disclosed in the specification for the understanding and reading in the art, and are not used to limit the conditions under which the present application can be implemented, so they have no technical substantive significance. Any modification of structures, change of proportional relationships or adjustment of sizes shall still fall within the scope covered by the technical content disclosed in the present application without affecting the effects that the present application can produce and the purpose that can be achieved.

FIG. 1 is a schematic diagram of a layout manner of a pixel opening and a support pillar in a conventional OLED display panel;

FIG. 2 is a cross-sectional view of the OLED display panel shown in FIG. 1 along P-P′;

FIG. 3 is a schematic diagram of another layout manner of a pixel opening and a support pillar in a conventional OLED display panel;

FIG. 4 is a cross-sectional view of the OLED display panel shown in FIG. 3 along A-A′;

FIG. 5 is a cross-sectional view of the display panel shown in FIG. 3;

FIG. 6 is a schematic diagram of a layout manner of a pixel opening and a first protrusion in a display panel according to an embodiment of the present application;

FIG. 7 is a cross-sectional view of the display panel shown in FIG. 6 along Q-Q′;

FIG. 8 is a schematic diagram of another layout manner of a pixel opening and a first protrusion in a display panel according to an embodiment of the present application;

FIG. 9 is a cross-sectional view of the display panel shown in FIG. 8 along C-C′;

FIG. 10 is a schematic diagram of still another layout manner of a pixel opening and a first protrusion in a display panel according to an embodiment of the present application;

FIG. 11 is a schematic diagram of still another layout manner of a pixel opening and a first protrusion in a display panel according to an embodiment of the present application;

FIG. 12 is a schematic diagram of still another layout manner of a pixel opening and a first protrusion in a display panel according to an embodiment of the present application;

FIG. 13 is a schematic diagram of still another layout manner of a pixel opening and a first protrusion in a display panel according to an embodiment of the present application;

FIG. 14 is a schematic diagram of an arrangement manner of sub-pixels in a display panel according to an embodiment of the present application;

FIG. 15 is a schematic diagram of still another layout manner of a pixel opening and a first protrusion in a display panel according to an embodiment of the present application;

FIG. 16 is a schematic diagram of an arrangement manner of sub-pixels in a display panel according to an embodiment of the present application;

FIG. 17 is a cross-sectional view of a display panel according to an embodiment of the present application;

FIG. 18 is a structural diagram of an electronic device according to an embodiment of the present application;

FIG. 19 is a flowchart of a manufacturing method according to an embodiment of the present application.

Reference numerals in the drawings are described as follows:

base substrate 100, pixel definition layer 101, support pillar 102, pixel opening 103, first pixel opening 1031, second pixel opening 1032, third pixel opening 1033, anode 104, first protrusion 105, conductive hole 106, pixel circuit 107, circuit layer 108, sub-pixel 109, organic light-emitting layer 110, base 111, cathode 112, second protrusion 113, display panel 114, red sub-pixel R, green sub-pixel G, blue sub-pixel B, first direction F1, second direction F2, first side S1, second side S2, third side S3, fourth side S4.

### DETAILED DESCRIPTION OF THE EMBODIMENTS

The embodiments of the present application will be clearly and completely described below with reference to the accompanying drawings in the embodiments of the present application. Those will appreciate that with the development of technology and the emergence of new scenarios, the embodiments provided in the embodiments of the present application are also applicable to similar problems.

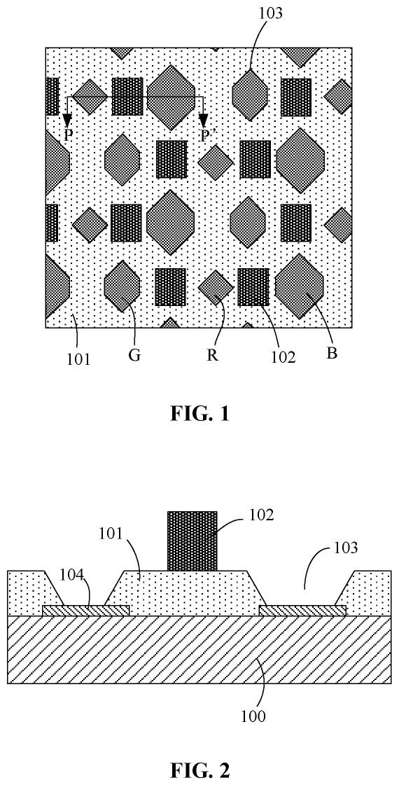

Referring to FIG. 1 and FIG. 2, FIG. 1 is a schematic diagram of a layout manner of a pixel opening and a support pillar in a conventional OLED display panel, and FIG. 2 is a cross-sectional view of the OLED display panel shown in FIG. 1 along P-P′. The display panel includes: a base substrate 100, an anode metal layer disposed on a surface of the base substrate 100 and including multiple anodes 104; a pixel definition layer 101 disposed on a surface of the anode metal layer facing away from the base substrate 100, the pixel definition layer 101 having multiple pixel openings 103. The pixel openings 103 are in one-to-one correspondence with the anodes 104 to expose at least part of the corresponding anodes 104. Sub-pixels are arranged in correspondence to the pixel openings 103. The display panel includes three types of sub-pixels with different light-emitting colors, namely a red sub-pixel R, a green sub-pixel G and a blue sub-pixel B. The sub-pixels are arranged in one-to-one correspondence with the pixel openings 103. Multiple support pillars 102 are formed on a surface of the pixel definition layer 101 facing away from the base substrate 100.

As shown in FIG. 2, in a conventional OLED display panel, in a process of evaporating a light-emitting layer of a sub-pixel in a pixel opening 103, multiple support pillars 102 for supporting a fine metal mask need to be formed on the surface of the pixel definition layer 101. The support pillars 102 are uniformly distributed on the surface of the pixel definition layer 101 and can only be arranged in the region away from the pixel openings 103, to reduce the influence of the pixel openings 103 on the stability of the support pillars 102. To ensure strength, a rigid display panel has a limitation for the distribution density of the support pillars 102 on the display panel, and thus the support pillar 102 is mostly designed in a strip shape. The density of rectangular support pillar 102 may be higher than the density of square support pillar. The distribution density accounts for about 10% of the display panel.

In the manner shown in FIG. 1 and FIG. 2, the support pillars 102 are made of a material different from the pixel definition layer 101. Thus, a separate manufacturing process for the support pillars needs to be added. In one embodiment, the support pillar 102 with a desired pattern structure need to be formed through coating and photolithography processes, resulting in complex manufacturing processes and increased cost.

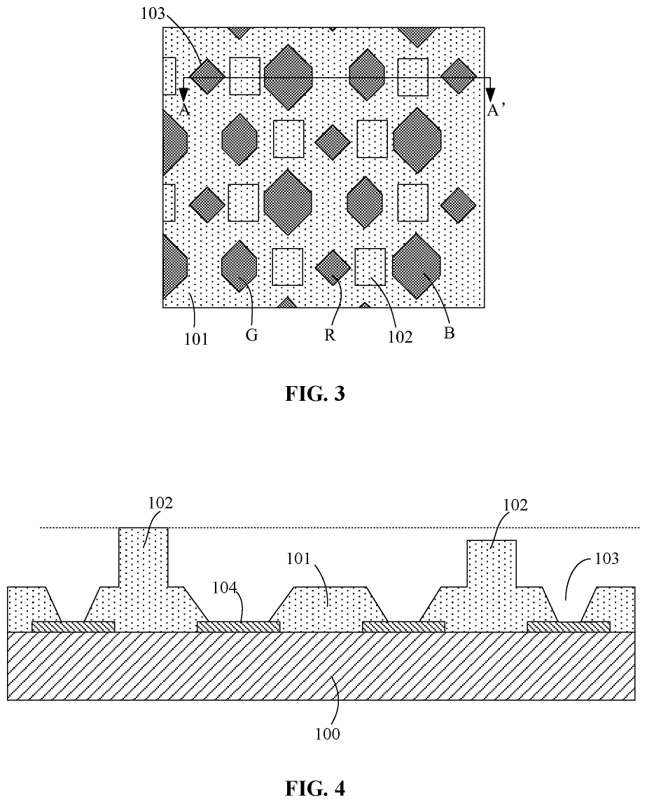

To solve the above problems, the pixel definition layer 101 can be used to manufacture the support pillar 102, as shown in FIG. 3 and FIG. 4.

Referring to FIG. 3 and FIG. 4, FIG. 3 is a schematic diagram of another layout manner of a pixel opening and a support pillar in a conventional OLED display panel, and FIG. 4 is a cross-sectional view of the OLED display panel shown in FIG. 3 along A-A′. The difference from the manner shown in FIG. 1 and FIG. 2 is that in the OLED display panel shown in FIG. 3 and FIG. 4, the support pillar 102 can be manufactured through the pixel definition layer 101. Thus, there is no need to use a separate film layer to manufacture the support pillar 102. The manufacturing process is simplified and the cost is reduced.

When the pixel definition layer 101 is used to manufacture the support pillar 102, the problem of collapse of the support pillar 102 is likely to occur. The inventor has found through research that the cause of this problem is that the organic material for manufacturing the pixel definition layer 101 has a fluidity before final curing. The organic material for manufacturing the pixel definition layer 101 may overflow from a higher position where the support pillar 102 is located to adjacent pixel openings 103. The larger the distance between a support pillar 102 and an adjacent pixel opening 103, the easier the overflow, resulting in a lower height of the support pillar 102. As shown in FIG. 3, since a support pillar 102 is opposite to a vertex angle of an adjacent pixel opening 103 on the left side and opposite to one side of an adjacent pixel opening 103 on the right side, the overflow degrees on the left and right sides of the support pillar 102 are different, which causes the support pillar 102 to be subjected to different acting forces from the adjacent pixel openings 103 on both sides. Thus, the problem of collapse of the support pillar 102 is likely to occur.

In addition, in this manner, part of the support pillars 102 (the left support pillar 102 in FIG. 4) are arranged between two pixel openings 103 with a small distance, and the distances between such part of the support pillars 102 and the adjacent pixel openings 103 are small; another part of the support pillars 102 (the right support pillar 102 in FIG. 4) are arranged between two pixel openings 103 with a large distance, and the distances between such part of the support pillars 102 and the adjacent pixel openings 103 are large. The larger the distance between a support pillar 102 and an adjacent pixel opening 103, the easier the overflow. The height of the left support pillar 102 is large while the height of the right support pillar 102 is low, as shown by the horizontal dashed line in FIG. 4. This causes the heights of the support pillars 102 in the display panel to be uneven, which affects the supporting effect of the support pillars 102 on the mask and further affects the evaporation quality of the light-emitting layer.

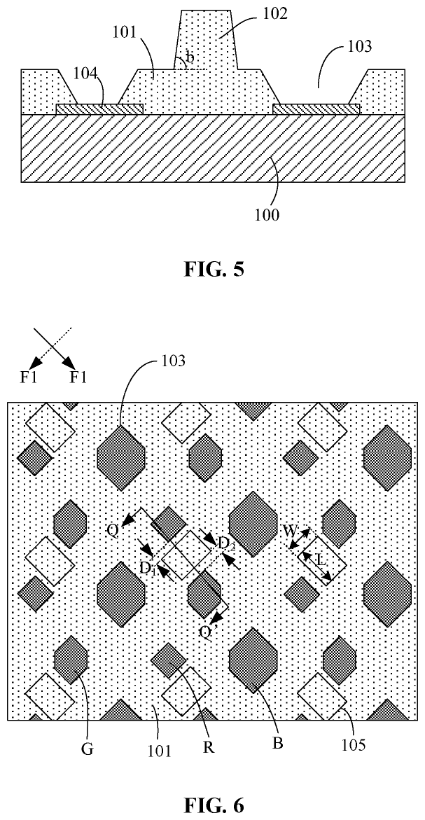

Referring to FIG. 5, FIG. 5 is a cross-sectional view of the display panel shown in FIG. 3. In the display panel, the side wall of a support pillar 102 is not strictly perpendicular to the upper surface of the pixel definition layer 101. The side wall of the support pillar 102 has an inclination angle b relative to the plane where the pixel definition layer 101 is located. The inclination angle b is greater than 0° and less than 90°. As described above, due to the existence of support pillars 102 with different overflow degrees in the display panel, not only the height uniformity of the support pillars 102 in the display panel is poor, but also the uniformity of the sidewall angle b of the support pillar 102 is poor, which leads to poor uniformity of the supporting effect of support pillars 102 on the mask and further affects the evaporation quality of the light-emitting layer.

In view of this, a display panel is provided according to an embodiment of the present application. The display panel includes: a base substrate; an anode metal layer disposed on a surface of the base substrate and including multiple anodes; a pixel definition layer disposed on a surface of the anode metal layer facing away from the base substrate.

The pixel definition layer includes: multiple pixel openings arranged corresponding to the anodes, where at least part of an anode of the anodes is exposed through a pixel opening corresponding to the anode; multiple first protrusions disposed on a surface of the pixel definition layer facing away from the base substrate, where each of the first protrusions is located between two adjacent pixel openings in a first direction, the first direction is parallel to a plane where the base substrate is located.

Each of the first protrusions has a first orthogonal projection on the plane where the base substrate is located, and each of the pixel openings has a second orthogonal projection on the plane. In the first direction, the first orthogonal projection is parallel to two adjacent second orthogonal projections.

In the embodiment of the present application, the pixel definition layer includes a first protrusion that may serve as a support pillar for supporting a mask. Therefore, in the present application, the film material of the pixel definition layer can be used to manufacture the support pillar. The first protrusion serving as the support pillar can be manufactured while the pixel definition layer with a desired pattern is manufactured, without using a separate film layer to manufacture the support pillar, thereby simplifying the manufacturing process of the display panel and reducing the cost. In addition, in the first direction, since the first orthogonal projection is parallel to two adjacent second orthogonal projections, the overflow difference between two adjacent pixel openings and the first protrusion can be reduced, the acting forces exerted by two adjacent pixel openings in the first direction on the first protrusion therebetween in the pixel definition layer can be balanced, the stability of the first protrusion can be improved, and the collapse of the first protrusion caused by uneven acting forces can be prevented.

To make the above objectives, features and advantages of the present application more understandable, the present application will be further described below with reference to the accompanying drawings and specific embodiments.

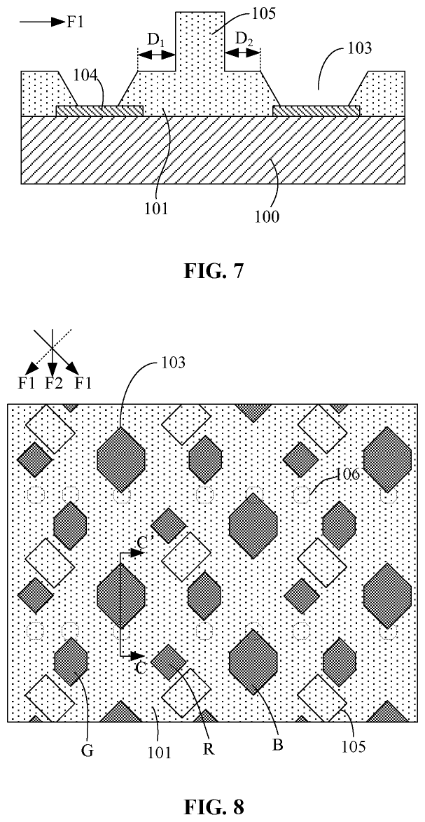

Referring to FIG. 6 and FIG. 7, FIG. 6 is a schematic diagram of a layout manner of a pixel opening and a first protrusion in a display panel according to an embodiment of the present application, and FIG. 7 is a cross-sectional view of the display panel shown in FIG. 6 along Q-Q′. The display panel includes: a base substrate 100; an anode metal layer disposed on a surface of the base substrate 100 and including multiple anodes 104; and a pixel definition layer 101 disposed on a surface of the anode metal layer facing away from the base substrate.

The pixel definition layer 101 includes: multiple pixel openings 103 arranged corresponding to the anodes, where each pixel opening 103 is correspondingly provided with one sub-pixel, the pixel openings 103 exposing at least part of an anode of the multiple anodes 104 is exposed through a pixel opening 103 corresponding to the anode; multiple first protrusions 105 disposed on a surface of the pixel definition layer 101 facing away from the base substrate 100, where each of the first protrusions 105 is located between two adjacent pixel openings 103 in a first direction F1, the first direction F1 is parallel to a plane where the base substrate 100 is located; each of the first protrusions 105 has a first orthogonal projection on the plane where the base substrate 100 is located, and each of the pixel openings 103 has a second orthogonal projection on the plane; and in the first direction F1, the first orthogonal projection is parallel to two adjacent second orthogonal projections. As shown in FIG. 7, in the embodiment of the present application, the first protrusions 105 and the pixel definition layer 101 are made of the same material layer, and thus the pixel definition layer 101 and the first protrusions 105 can be manufactured in the same process.

For two pixel openings 103 adjacent in the first direction F1, the two second orthogonal projections corresponding to the two pixel openings 103 each have a side perpendicular to the first direction F1. Those two sides of the two second orthogonal projections perpendicular to the first direction F1 are parallel and opposite. The first orthogonal projection of the first protrusion 105 is located between the two parallel and opposite sides of the two second orthogonal projections. The first orthogonal projection has two parallel and opposite sides perpendicular to the first direction F1. The sides of the first orthogonal projection perpendicular to the first direction F1 are respectively parallel and opposite to the two sides of adjacent second orthogonal projections. In one embodiment, the first orthogonal projection is parallel to two adjacent second orthogonal projections in the first direction F1.

In the display panel according to the embodiment of the present application, the first protrusion 105 can serve as the support pillar for supporting a mask. Therefore, the film material of the pixel definition layer 101 can be used to manufacture the support pillar. The first protrusion 105 serving as the support pillar can be manufactured while the pixel definition layer 101 with a desired pattern is manufactured, without using a separate film layer to manufacture the support pillar, thereby simplifying the manufacturing process of the display panel and reducing the cost. In the first direction F1, since the first orthogonal projection is parallel to two adjacent second orthogonal projections, the overflow difference between two adjacent pixel openings 103 and the first protrusion 105 can be reduced, the acting forces exerted by two adjacent pixel openings 103 in the first direction F1 on the first protrusion 105 therebetween in the pixel definition layer 101 can be balanced, the stability of the first protrusion 105 can be improved, and the collapse of the first protrusion 105 caused by uneven acting forces can be prevented.

In some implementations, on the basis of other implementations, in the first direction F1, the minimum distances between the first protrusion 105 and two adjacent pixel openings 103 in the first direction F1 are greater than 3 μm. That is, the minimum distance between a first orthogonal projection and a second orthogonal projection adjacent to each other is greater than 3 μm. As shown in FIG. 6 and FIG. 7, in the first direction F1, the minimum distances between the first protrusion 105 and two adjacent pixel openings 103 are D₁ and D₂ respectively, where D₁>3 μm, D₂>3 μm. This manner can prevent the etching of the first protrusion 105 and the etching of the pixel opening 103 from interfering with each other during the etching process of the pixel definition layer 101 due to an excessively small distance between the first protrusion 105 and the pixel opening 103, avoid the etching interference from affecting the pattern morphology of the first protrusion 105 and the pixel opening 103, and also avoid the etching interference from affecting the stability of the first protrusion 105.

In an embodiment, on the basis of other implementations, in the first direction F1, the minimum distances between the first protrusion 105 and two adjacent pixel openings 103 are equal, that is, D₁=D₂. When the distances between the first protrusion 105 and two adjacent pixel openings 103 in the first direction F1 are equal, the design of the distances between the first protrusion 105 and two adjacent pixel openings 103 is facilitated, and the two pixel openings 103 can exert relatively uniform acting forces on the first protrusion 105 therebetween, so that the first protrusion 105 has good stability.

Further, D₁=D₂>3 m can be set. In this way, not only the etching interference between the first protrusion 105 and the adjacent pixel openings 103 in the first direction F1 can be effectively avoided, but also the acting force difference between the two pixel openings 103 on the first protrusion 105 therebetween can be reduced, and the stability of the first protrusion 105 can be better improved.

In some embodiments, on the basis of other implementations, as shown in FIG. 7, the first orthogonal projection is rectangular, and the long side of the rectangle is perpendicular to the first direction F1. For a given display panel, the distance between two adjacent pixel openings 103 in the first direction F1 is a fixed value. In this manner, since the long side of the rectangle corresponding to the first orthogonal projection is perpendicular to the first direction F1, the short side of the rectangle corresponding to the first orthogonal projection can be parallel to the first direction F1. When the distance between two adjacent pixel openings 103 in the first direction F1 is determined, the minimum distances between the first orthogonal projection and two adjacent second orthogonal projections have a relatively large value, that is, relatively large D₁ and D₂ can be obtained. Thus, the etching interference between the first protrusion 105 and two adjacent pixel openings 103 can be better reduced, and the stability of the first protrusion 105 can be improved.

In some embodiments of the present application, on the basis of other implementations, when the first orthogonal projection is rectangular, the aspect ratio of the rectangle is not greater than 1.5. As shown in FIG. 6, the length of the first orthogonal projection is L and the width is W, then L/W≤1.5. This aspect ratio can improve the stability of the first protrusion 105 and prevent the collapse problem and the scratch problem of the first protrusion 105 on the mask caused by an excessively large aspect ratio.

In one embodiment, in some embodiments of the present application, the distances between two adjacent pixel openings 103 in the first direction F1 are the same. In one embodiment, each first protrusion 105 can be located between two pixel openings 103 with the same distance, and each first protrusion 105 is located between two pixel openings 103 with the same distance. Thus, respective first protrusions 105 can have the same overflow degree, and can have relatively consistent heights and sidewall angles.

The display panel includes multiple sub-pixels in one-to-one correspondence with the pixel openings 103. The multiple sub-pixels include a red sub-pixel R, a green sub-pixel G and a blue sub-pixel B. Each pixel opening 103 is correspondingly provided with one sub-pixel.

In an embodiment, a first protrusion 105 can be arranged between the pixel openings 103 corresponding to a first sub-pixel and a second sub-pixel adjacent in the first direction F1. The first sub-pixel is one of the red sub-pixel R, the green sub-pixel G and the blue sub-pixel B, and the second sub-pixel is another one of the red sub-pixel R, the green sub-pixel G and the blue sub-pixel B.

In the manner shown in FIG. 6, one of the first sub-pixel and the second sub-pixel is the red sub-pixel R, and the other one is the green sub-pixel G. Generally, to improve display uniformity, the blue sub-pixel B has the largest light-emitting area. That is, the size of the pixel opening 103 corresponding to the blue sub-pixel B is larger than the size of the pixel opening 103 corresponding to the red sub-pixel R and larger than the size of the pixel opening 103 corresponding to the green sub-pixel G. Therefore, the distance between the pixel openings 103 corresponding to the red sub-pixel R and green sub-pixel G adjacent to each other is large. By arranging the first protrusion 105 in the region corresponding to this distance, a large distance between the first protrusion 105 and two adjacent pixel openings 103 can be obtained, to reduce the etching interference between the first protrusion 105 and the pixel openings 103.

In the display panel, since organic light-emitting materials of sub-pixels with different light-emitting colors have different luminous efficiencies, the red sub-pixel R, the green sub-pixel G and the blue sub-pixel B correspond to pixel openings 103 with different areas respectively, to improve the display uniformity of the display panel. Thus, sub-pixels with different light-emitting colors have different light-emitting areas. As shown in FIG. 6, the areas of the pixel openings 103 corresponding to the red sub-pixel R, the green sub-pixel G and the blue sub-pixel B increase in sequence. Two pixel openings 103 corresponding to first and second sub-pixels adjacent to each other exert a first overflow degree on the first protrusion 105 therebetween. Two pixel openings 103 corresponding to second and third sub-pixels adjacent to each other exert a second overflow degree on the first protrusion 105 therebetween. Two pixel openings 103 corresponding to first and third sub-pixels adjacent to each other exert a third overflow degree on the first protrusion 105 therebetween. The first overflow degree, the second overflow degree and the third overflow degree are different, due to different distances between sub-pixels and different areas of pixel openings 103 corresponding to sub-pixels.

When the first protrusion 105 is arranged between the pixel openings 103 corresponding to the first sub-pixel and the second sub-pixel adjacent in the first direction F1, each first protrusion 105 can be located between the pixel openings 103 corresponding to the first sub-pixel and second sub-pixel adjacent to each. Thus, each first protrusion 105 corresponds to the first overflow degree, thereby avoiding differences in height and sidewall angle of each first protrusion 105 caused by different overflow degrees, and improving the height uniformity and sidewall angle uniformity of the first protrusions 105.

In some embodiments of the present application, on the basis of other implementations, the area ratio of the first protrusions 105 accounts for no less than 6% of a display region of the display panel. That is, the area of all first protrusions 105 in the display region account for no less than 6% of the total area of the display region, to avoid the problem of insufficient supporting force of the first protrusions 105 on the mask caused by an excessively small area ratio.

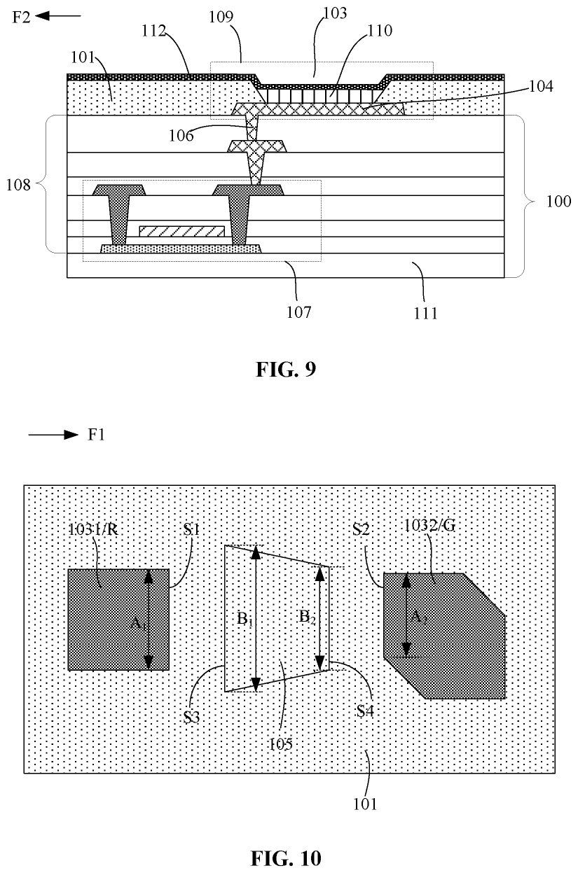

Referring to FIG. 8 and FIG. 9, FIG. 8 is a schematic diagram of another layout manner of a pixel opening and a first protrusion in a display panel according to an embodiment of the present application, and FIG. 9 is a cross-sectional view of the display panel shown in FIG. 8 along C-C′. On the basis of other implementations, the display panel further includes: a pixel circuit 107, the anode 104 being connected to the pixel circuit 107 through a conductive hole 106; the conductive hole 106 located between two adjacent pixel openings 103 in a second direction F2. The second direction F2 is parallel to the plane where the base substrate 100 is located and intersects the first direction F1.

When the first protrusion 105 and the conductive hole 106 for connecting the anode 104 and the pixel circuit 107 are arranged in different sub-pixel gaps, the conductive hole 106 and the first protrusion 105 can be prevented from overlapping in a direction perpendicular to the plane where the base substrate 100 is located. Thus, a relatively large distance can be provided between the conductive hole 106 and the first protrusion 105 in a direction parallel to the plane where the base substrate 100 is located, thereby reducing or eliminating the acting force of the conductive hole 106 on the first protrusion 105, preventing the collapse of the first protrusion 105 caused by an excessively small distance between the conductive hole 106 and the first protrusion 105, and avoiding the influence of the conductive hole 106 on the stability of the first protrusion 105.

As shown in FIG. 9, the base substrate 100 includes a base 111. The base 111 may be a rigid base, such as a glass plate or a hard plastic plate. The base 111 may also be a bendable flexible base, such as a polyimide base or a polyester base. A circuit layer 108 is arranged on a surface of the base 111. The circuit layer 108 includes a pixel circuit 107. An anode metal layer and a pixel definition layer 101 are arranged on a surface of the circuit layer 108 facing away from the base 111. Sub-pixels 109 are arranged corresponding to the pixel openings 103 of the pixel definition layer 101. The sub-pixel 109 includes an organic light-emitting layer 110 located in the pixel opening 103. The organic light-emitting layer 110 is located on a surface of the anode 104 exposed by the pixel opening 103. The sub-pixel 109 further includes a common cathode 112.

In some embodiments of the present application, on the basis of other implementations, in a direction parallel to the plane where the base substrate 100 is located, the distance between the first protrusion 105 and the conductive hole 106 adjacent to the first protrusion 105 is greater than 3 μm. In this manner, the distance between the first orthogonal projection and an orthogonal projection of the conductive hole 106 on the plane where the base substrate 100 is located is greater than 3 μm, which can avoid a large stress exerted by the conductive hole 106 on the first protrusion 105 due to an excessively small distance between the conductive hole 106 and the first protrusion 105, and prevent the stress from causing the collapse of the first protrusion 105.

Referring to FIG. 10, FIG. 10 is a schematic diagram of still another layout manner of a pixel opening and a first protrusion in a display panel according to an embodiment of the present application. For clarity of illustration, only a first pixel opening 1031, a second pixel opening 1032 adjacent to the first pixel opening 1031 in the first direction F1, and a first protrusion 105 located between the first pixel opening 1031 and the second pixel opening 1032 are shown in FIG. 10.

On the basis of other manners, in the display panel shown in FIG. 10, multiple pixel openings 103 of the display panel include: a first pixel opening 1031, and a second pixel opening 1032 adjacent to the first pixel opening 1031 in the first direction F1. The first pixel opening 1031 corresponds to a first sub-pixel, and the second pixel opening 1032 corresponds to a second sub-pixel. The first sub-pixel and the second sub-pixel have different light-emitting colors. In an embodiment, one of the first sub-pixel and the second sub-pixel is the red sub-pixel R, and the other one is the green sub-pixel G.

As shown in FIG. 10, the pixel definition layer 101 between the first pixel opening 1031 and the second pixel opening 1032 includes a first protrusion 105. The second orthogonal projection corresponding to the first pixel opening 1031 has a first side S1, the second orthogonal projection corresponding to the second pixel opening 1032 has a second side S2, and the first side S1 and the second side S2 are parallel and opposite in the first direction F1. The first orthogonal projection corresponding to the first protrusion 105 is located between the first side S1 and the second side S2. The first orthogonal projection has a third side S3 parallel and opposite to the first side S1, and a fourth side S4 parallel and opposite to the second side S2. The length of the first side S1 is A₁, the length of the second side S2 is A₂, the length of the third side S3 is B₁, and the length of the fourth side S4 is B₂; where A₁>A₂ and B₁>B₂.

For a pixel opening 103 adjacent to the first protrusion 105, the longer the side of the second orthogonal projection opposite to the first projection, the larger the influence range on the stability of the first protrusion 105. In view of this, different from a rectangular first orthogonal projection, the lengths of two adjacent sides (the third surface S3 and the fourth side S4) of the first orthogonal projection in the first direction F1 are related to the lengths of the sides of an second orthogonal projections adjacent to the first orthogonal projection, in the manner shown in FIG. 10. Thus, the acting forces of pixel openings 103 of different sizes on the first protrusion 105 can be balanced to better ensure the stability of the first protrusion 105.

Generally, for first and second sub-pixels with different light-emitting colors, the first pixel opening 1031 and the second pixel opening 1032 have different sizes, A₁≠A₂. When A₁>A₂, B₁>B₂.

In an embodiment,

$$\frac{{A}_{1}}{{A}_{2}} = {K}_{1} \frac{{B}_{1}}{{B}_{2}} ,$$

where K₁ is a set positive constant. In this way, the ratio

$$\frac{{B}_{1}}{{B}_{2}}$$

of the lengths of the third side S3 to the fourth side S4 is positively correlated with the ratio

$$\frac{{A}_{1}}{{A}_{2}}$$

of the lengths of the first side S1 to the second side S2. Thus, the acting forces of the first pixel opening 1031 and the second pixel opening 1032 on the first protrusion 105 therebetween can be better balanced to ensure the stability of the first protrusion 105. K₁ is a known preset positive constant, which can be an empirical constant.

As described above, the first orthogonal projection may also be rectangular. When A₁>A₂, B₁=B₂ can be set.

On the basis of other implementations, B₁>A₁, B₂>A₂, the orthogonal projection of the first side S1 on the third side S3 is located between two ends of the third side S3. The orthogonal projection of the second side S2 on the fourth side S4 is located between two ends of the fourth side S4. In this way, ends of the third side S3 and the fourth side S4 may be far away from the corresponding pixel openings 103, to reduce the overflow influence of the pixel openings 103 on the adjacent first protrusion 105 and improve the stability of the first protrusion 105.

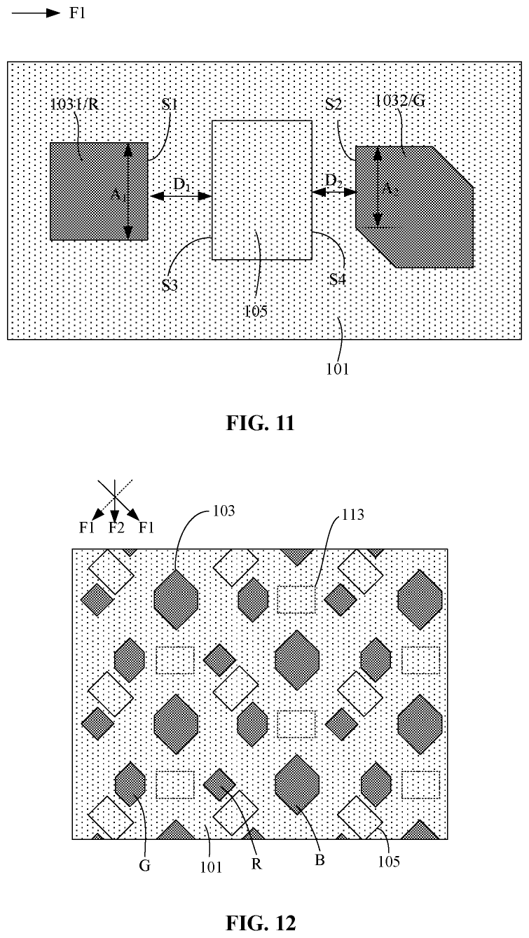

Referring to FIG. 11, FIG. 11 is a schematic diagram of still another layout manner of a pixel opening and a first protrusion in a display panel according to an embodiment of the present application. For clarity of illustration, only a first pixel opening 1031, a second pixel opening 1032 adjacent to the first pixel opening 1031 in the first direction F1, and a first protrusion 105 located between the first pixel opening 1031 and the second pixel opening 1032 are shown in FIG. 11.

On the basis of other manners, in the display panel shown in FIG. 11, for the first pixel opening 1031 and the second pixel opening 1032 adjacent to each other in the first direction F1, the first side S1 of the second orthogonal projection corresponding to the first pixel opening 1031 and the second side S2 of the second orthogonal projection corresponding to the second pixel opening 1032 are parallel and opposite in the first direction F1. The length of the first side S1 is A₁, and the length of the second side S2 is A₂. A first protrusion 105 is arranged between the first pixel opening 1031 and the second pixel opening 1032. The distance between the first orthogonal projection corresponding to the first protrusion 105 and the first side S1 is D₁, and the distance between the first orthogonal projection and the second side S2 is D₂, wherein A₁>A₂ and D₁>D₂.

In FIG. 11, the first orthogonal projection is a rectangle as an example, which has a third side S3 parallel and opposite to the first side S1 and a fourth side S4 parallel and opposite to the second side S2. The distance between the first side S1 and the third side S3 is D₁, and the distance between the second side S2 and the fourth side S4 is D₂. In other manners, the lengths of the third side S3 and the fourth side S4 in the first orthogonal projection may be unequal, for example, A₁>A₂ and B₁>B₂. In this case, the first orthogonal projection can be trapezoidal.

For a pixel opening 103 adjacent to the first protrusion 105, the longer the side of the second orthogonal projection opposite to the first projection, the larger the influence range on the stability of the first protrusion 105. In view of this, in the manner shown in FIG. 11, A₁>A₂ and D₁>D₂. Thus, the acting forces of the first side S1 and the second side S2 on the first protrusion 105 therebetween can be balanced to improve the stability of the first protrusion 105.

In an embodiment,

$$\frac{{A}_{1}}{{A}_{2}} = {K}_{2} \frac{{D}_{1}}{{D}_{2}} ,$$

where K₂ is a set positive constant. In this way, for the first pixel opening 1031, the second pixel opening 1032 adjacent to the first pixel opening 1031 in the first direction F1, and the first protrusion 105 located therebetween, the ratio

$$\frac{{D}_{1}}{{D}_{2}}$$

of the distances between the first orthogonal projection and two adjacent second orthogonal projections is positively correlated with the ratio

$$\frac{{A}_{1}}{{A}_{2}}$$

of the lengths of the sides of the two second orthogonal projections corresponding to the first orthogonal projection. Thus, the acting forces of the first pixel opening 1031 and the second pixel opening 1032 on the first protrusion 105 therebetween can be better balanced to ensure the stability of the first protrusion 105. K₂ is a known preset positive constant, which can be an empirical constant.

Referring to FIG. 12, FIG. 12 is a schematic diagram of still another layout manner of a pixel opening and a first protrusion in a display panel according to an embodiment of the present application. On the basis of other implementations, in the display panel shown in FIG. 12, the pixel definition layer 101 further includes a second protrusion 113. The second protrusion 113 is located between two adjacent pixel openings 103 in a second direction F2. The second direction F2 is parallel to the plane where the base substrate 100 is located and intersects the first direction F1. In this manner, by adding the second protrusions 113 between two adjacent pixel openings 103 in the second direction F1, the area ratio of the support structure on the surface of the pixel definition layer 101 can be increased, to improve the support stability and strength for the mask.

When the pixel definition layer 101 further includes the second protrusion 113, the second protrusion 113 has a third orthogonal projection on the plane where the base substrate 100 is located. As shown in FIG. 12, the first orthogonal projection and the third orthogonal projection can be set to be congruent geometric figures, and the first protrusion 105 and the second protrusion 113 have the same geometric structure, which facilitates the process manufacturing of the pixel definition layer 101 and reduces the manufacturing process difficulty of the display panel.

In an embodiment, the ratio of the first protrusion 105 to the total area is greater than the ratio of the second protrusion 113 to the total area. In one embodiment, the first protrusions 105 with high stability have a large area ratio, to improve the support stability and reliability for the mask.

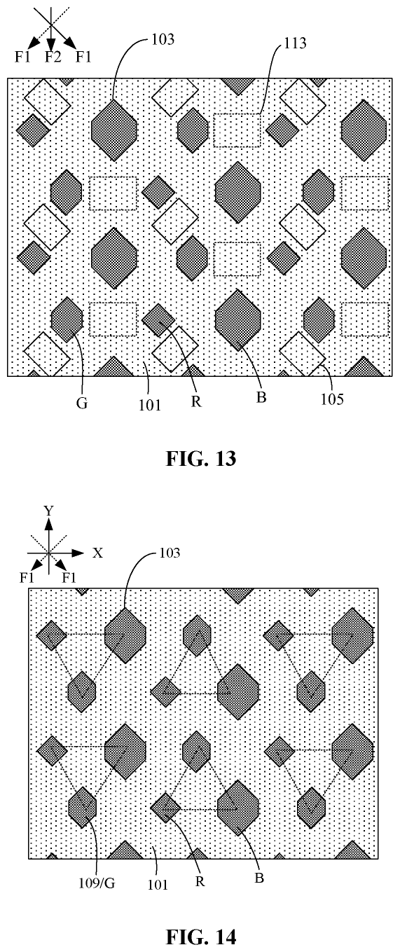

Referring to FIG. 13, FIG. 13 is a schematic diagram of still another layout manner of a pixel opening and a first protrusion in a display panel according to an embodiment of the present application. On the basis of other implementations, in the display panel shown in FIG. 13, the pixel definition layer 101 further includes a second protrusion 113, which can increase the area ratio of the support structure on the surface of the pixel definition layer 101, to improve the support stability and strength for the mask. In addition, different from the manner shown in FIG. 12, in the display panel shown in FIG. 13, the first orthogonal projection and the third orthogonal projection have similar geometric figures, and the area of the third orthogonal projection is larger than that of the first orthogonal projection. This manner can improve the support stability and strength for the mask by increasing the area of the second protrusions 113.

In other manners, geometry of the third orthogonal projection may not be similar to geometry of the first orthogonal projection. In this case, the third orthogonal projection and the first orthogonal projection may have different geometric figures. For example, the first orthogonal projection is rectangular, and the third orthogonal projection is any one of square, circle and triangle. In this manner, the graphic structure of the second protrusions 113 can be designed in a more diversified manner, facilitating adjusting the distribution and area ratio of the protrusion structures through the second protrusions 113, to better adjust the support performance for the mask.

In some embodiments of the present application, on the basis of other implementations, as shown in FIG. 12 or FIG. 13, the first orthogonal projection and the third orthogonal projection are both rectangular. The minimum included angle between the long side of the first orthogonal projection and the long side of the third orthogonal projection is 45°. In this manner, the long sides of the first protrusion 105 and the second protrusion 113 have different directions. The long side of the first protrusion 105 is perpendicular to the first direction, the long side of the second protrusion 113 is perpendicular to the second direction, and the minimum included angle of the long sides of the first protrusion 105 and the second protrusion 113 is 45°. Thus, the first protrusion 105 may have a large distance from two adjacent pixel openings 103 in the first direction F1, and the second protrusion 113 may have a large distance from two adjacent pixel openings 103 in the second direction F2, to improve the stability of the first protrusion 105 and the second protrusion 113.

In an embodiment, the aspect ratios of the rectangles corresponding to the first protrusion 105 and the second protrusion 113 can both be less than 1.5.

In the manners shown in FIG. 1, FIG. 3, FIG. 6, FIG. 8, FIG. 12 and FIG. 13, sub-pixels in the display panel adopt a pyramid arrangement.

Referring to FIG. 14, FIG. 14 is a schematic diagram of a sub-pixel arrangement manner in a display panel according to an embodiment of the present application. On the basis of other manners, in the manner shown in FIG. 14, the pixel definition layer 101 includes multiple pixel openings 103 arranged in a dot matrix. Each pixel opening 103 is correspondingly provided with one sub-pixel 109. The display panel includes multiple pyramid pixel units arranged in an array. The pyramid pixel unit is shown by a dashed triangle in FIG. 14 and includes three sub-pixels 109 with different light-emitting colors, namely a red sub-pixel R, a green sub-pixel G and a blue sub-pixel B. In this manner, the first direction F1 intersects both the row direction X and the column direction Y of the pyramid pixel unit array. The first direction F1 can include at least one of the dashed arrows shown in FIG. 14. The first direction F1 is inclined at 45° relative to the row direction X and the column direction Y.

In the manner shown in FIG. 14, the display panel includes three types of sub-pixels 109 with different light-emitting colors, namely a red sub-pixel R, a green sub-pixel G and a blue sub-pixel B. The display panel includes M rows of sub-pixels 109, where M is a positive integer. In one row, any three consecutive sub-pixels 109 have different light-emitting colors. For the (2i−1)-th row and the 2i-th row, the j-th sub-pixel in the 2i-th row is located between the j-th sub-pixel and the (j+1)-th sub-pixel in the (2i−1)-th row. Thus, the sub-pixels 109 in two adjacent rows are arranged in a staggered manner to form a pyramid distribution design as shown in FIG. 14. In the above display panel, j is a positive integer, j is not greater than J, and J is the number of sub-pixels 109 in one row; i is a positive integer, and 2i is not greater than M.

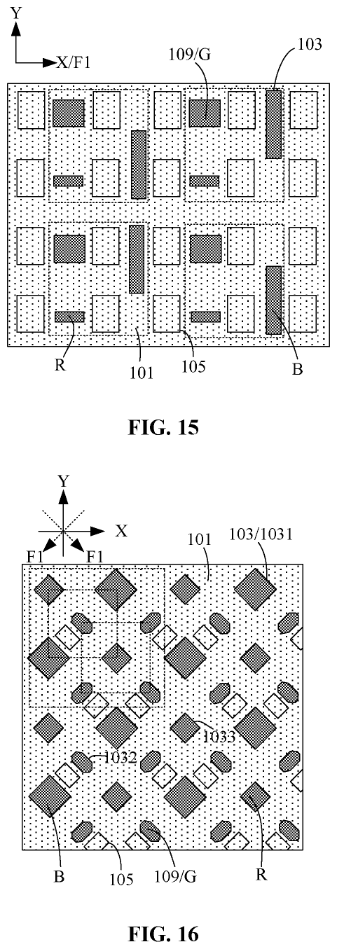

Referring to FIG. 15, FIG. 15 is a schematic diagram of still another layout manner of a pixel opening and a first protrusion in a display panel according to an embodiment of the present application. On the basis of other implementations, in the display panel shown in FIG. 15, the pixel definition layer 101 includes multiple pixel openings 103 arranged in a dot matrix, and each pixel opening 103 is correspondingly provided with one sub-pixel 109. The first protrusions 105 in the pixel definition layer 101 are located between two adjacent pixel openings 103 in the first direction F1. The sub-pixels 109 in the display panel adopt a Pi( ) arrangement. The display panel includes multiple pixel units arranged in an array (shown by a dashed rectangular box in FIG. 15). The pixel unit includes three sub-pixels 109 with different light-emitting colors. The first direction F1 may include at least one of the row direction X and the column direction Y of the pixel unit array. FIG. 15 is illustrated by taking the first direction F1 as the row direction X as an example.

In the manner shown in FIG. 15, the display panel includes three types of sub-pixels 109 with different light-emitting colors, namely a red sub-pixel R, a green sub-pixel G and a blue sub-pixel B. In the pixel units in one column, the red sub-pixels R and the green sub-pixels G are alternately arranged on one straight line in the column direction Y, the blue sub-pixels B are located on one straight line in the column direction Y, and the blue sub-pixels B are located on different straight lines from the red sub-pixels R and the green sub-pixels G. In the pixel units in one row, the red sub-pixels R are located on one straight line in the row direction X, the green sub-pixels G are located on one straight line in the row direction X, and the red sub-pixels R and the green sub-pixels G are located on different straight lines.

Referring to FIG. 16, FIG. 16 is a schematic diagram of a sub-pixel arrangement manner in a display panel according to an embodiment of the present application. On the basis of other implementation, in the manner shown in FIG. 16, the pixel definition layer 101 includes multiple pixel openings 103 arranged in a dot matrix, and each pixel opening 103 is correspondingly provided with one sub-pixel 109. The display panel includes multiple windmill-shaped pixel units arranged in an array (shown by a large dashed box in FIG. 16). In this manner, each sub-pixel 109 in the display panel adopts a windmill arrangement. The windmill-shaped pixel unit includes two sub-pixel units (shown by small dashed boxes in FIG. 16), and each sub-pixel unit includes four sub-pixels 109. In one windmill-shaped pixel unit, one sub-pixel unit includes two red sub-pixels R and two blue sub-pixels B, the four sub-pixels 109 are located at four vertex angles of a rectangle, the two red sub-pixels R are diagonally distributed, and the two blue sub-pixels B are diagonally distributed; the other sub-pixel unit includes four green sub-pixels G distributed on a rectangle. In this manner, the first direction F1 intersects both the row direction X and the column direction Y of the windmill-shaped pixel unit array, and the first direction F1 may include at least one of the dashed arrows shown in FIG. 16. The first direction F1 is inclined at 450 relative to the row direction X and the column direction Y.

In the manner shown in FIG. 16, the display panel includes three types of sub-pixels 109 with different light-emitting colors, namely a red sub-pixel R, a green sub-pixel G and a blue sub-pixel B. The display panel includes M rows of sub-pixels 109, where M is a positive integer. Each sub-pixel 109 in the (2i−1)-th row is the red sub-pixels R and the blue sub-pixels B arranged alternately, and each sub-pixel 109 in the 2i-th row is the green sub-pixels. For the (2i−1)-th row and the 2i-th row, the j-th sub-pixel in the 2i-th row is located between the j-th sub-pixel and the (j+1)-th sub-pixel in the (2i−1)-th row, and the j-th sub-pixel in the (2i−1)-th row and the j-th sub-pixel in the 2i-th row are a red sub-pixel R and a blue sub-pixel B respectively, and the sub-pixels 109 in two adjacent rows are arranged in a staggered manner to form a windmill arrangement design as shown in FIG. 16 j is a positive integer, j is not greater than J, and J is the number of sub-pixels 109 in one row; i is a positive integer, and 2i is not greater than M.

As shown in FIG. 16, multiple pixel openings 103 in the display panel include a first pixel opening 1031, a second pixel opening 1032 and a third pixel opening 1033. The first pixel opening 1031, the second pixel opening 1032 and the third pixel opening 1033 correspond to sub-pixels 109 with different light-emitting colors respectively. When the display panel is provided with both the first protrusion 105 and the second protrusion 113, the first protrusion 105 is located between the first pixel opening 1031 and the second pixel opening 1032; the second protrusion 113 is located between the second pixel opening 1032 and the third pixel opening 1033. In the manner shown in FIG. 16, the first pixel opening 1031 corresponds to the blue sub-pixel B, the second pixel opening 1032 corresponds to the green sub-pixel G, and the third pixel opening 1033 corresponds to the red sub-pixel R as an example for illustration.

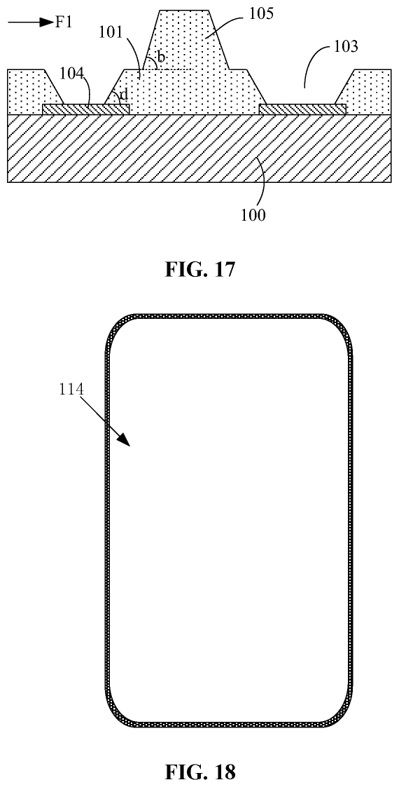

Referring to FIG. 17, FIG. 17 is a cross-sectional view of a display panel according to an embodiment of the present application. The first protrusion 105 is located between two adjacent pixel openings 103 in the first direction F1. In a cross-sectional view parallel to the first direction F1, the sidewall angle b of the first protrusion 105 and the sidewall angle d of the pixel opening 103 are both 10° to 30°.

In the conventional technology, if the support pillars are made of a separate material, the sidewall angle of the support pillar and the sidewall angle of the pixel opening 103 are relatively large.

Compared with the support pillars made of the separate material in the conventional technology, when the pixel opening 103 and the first protrusion 105 are integrally manufactured through the pixel definition layer 101, the sidewall angle b of the first protrusion 105 and the sidewall angle d of the pixel opening 103 are relatively small. Thus, the sidewall angle b of the first protrusion 105 can be matched with the sidewall angle d of the pixel opening 103, to reduce the difference of acting forces of the pixel openings 103 on both sides on the first protrusion 105 and improve the stability of the first protrusions 105.

Since the pixel opening 103 and the first protrusion 105 are manufactured based on the same exposure process, to ensure the exposure intensity of the pixel openings 103 and prevent insufficient exposure in the region corresponding to the deep pixel opening 103 from affecting the morphology of the pixel openings 103, the sidewall angle d of the pixel opening 103 can be set to be greater than the sidewall angle b of the first protrusion 105.

On the basis of the display panel provided in the above embodiments, an electronic device is provided according to another embodiment of the present disclosure. The structure of the electronic device can be as shown in FIG. 18.

Referring to FIG. 18, FIG. 18 is a structural diagram of an electronic device according to an embodiment of the present application. The electronic device includes the display panel 114 according to any one of the above embodiments. The electronic device can be any electronic apparatus with a display function, such as a mobile phone, a tablet computer and a wearable device.

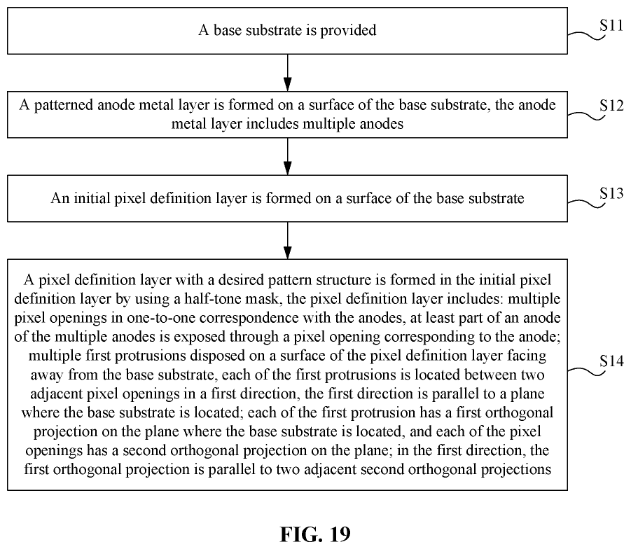

On the basis of the display panel provided in the above embodiments, a manufacturing method of a display panel is provided according to another embodiment of the present disclosure. The manufacturing method can be as shown in FIG. 19.

Referring to FIG. 19, FIG. 19 is a flowchart of a manufacturing method according to an embodiment of the present application. The manufacturing method includes steps S11 to S14.

In Step S11, a base substrate 100 is provided.

In Step S12, a patterned anode metal layer is formed on a surface of the base substrate, and the anode 104 metal layer includes multiple anodes 104.

In Step S13, an initial pixel definition layer is formed on a surface of the base substrate 100.

In Step S14, a pixel definition layer with a desired pattern structure is formed in the initial pixel definition layer by using a half-tone mask, the pixel definition layer includes: multiple pixel openings 103 in one-to-one correspondence with the anodes 104, at least part of an anode of the multiple anodes 104 is exposed through a pixel opening 103 corresponding to the anode; multiple first protrusions 105 disposed on a surface of the pixel definition layer facing away from the base substrate 100, each of the first protrusions 105 is located between two adjacent pixel openings 103 in a first direction F1, the first direction F1 is parallel to a plane where the base substrate 100 is located.

Each of the first protrusion 105 has a first orthogonal projection on the plane where the base substrate 100 is located, and each of the pixel openings 103 has a second orthogonal projection on the plane; in the first direction F1, the first orthogonal projection is parallel to two adjacent second orthogonal projections.

The electronic device and the manufacturing method disclosed in the above embodiments have the same or corresponding beneficial effects as those of the display panel embodiments, which will not be repeated herein.

The various embodiments in the specification of the present application are described in a progressive, parallel, or progressive and parallel combination manner, each embodiment focuses on the differences from other embodiments, and the same and similar parts between the various embodiments can be referred to each other. The embodiments provided in the embodiments of the present application can be combined with each other without contradiction.

In the description of the present application, the descriptions of the accompanying drawings and the embodiments are illustrative rather than restrictive. The same reference numerals throughout the embodiments of the specification indicate the same structure. In addition, for ease of understanding and description, the accompanying drawings may exaggerate the thicknesses of some layers, films, panels, regions and the like. It will also be understood that when an element such as a layer, film, region or substrate is referred to as being “on” another element, it can be directly on the other element or intervening elements may also be present. In addition, “on” refers to positioning an element on or under another element, but essentially not on the upper side of another element according to the direction of gravity.

The terms “upper”, “lower”, “top”, “bottom”, “inner”, “outer” and the like indicate orientations or positional relationships based on those shown in the accompanying drawings, which are for convenience of describing the present application and simplifying the description, and do not indicate or imply that the referred device or element must have a specific orientation, be constructed and operated in a specific orientation, and thus should not be construed as limiting the present application. When a component is considered to be “connected” to another component, it can be directly connected to the other component or intervening components may be present.

It should also be noted that in this document, relational terms such as first and second are used solely to distinguish one entity or operation from another entity or operation without necessarily requiring or implying any actual such relationship or order between such entities or operations. Furthermore, the terms “comprising”, “including” or any other variation thereof are intended to cover a non-exclusive inclusion, and an article or apparatus that includes a list of elements includes not only those elements but also other elements not expressly listed or inherent to such article or apparatus. Without further limitation, an element defined by the statement “comprising a . . . ” does not exclude the presence of other identical elements in the article or apparatus including said element.

The above description of the disclosed embodiments enables those to implement or use the present application. Various modifications to these embodiments will be readily apparent in the art, and the general principles defined herein may be implemented in other embodiments without departing from the spirit or scope of the present application. Therefore, the present application will not be limited to the embodiments shown herein, but is to be accorded the widest scope consistent with the principles and novel features disclosed herein.

What is claimed is:

1. A display panel, comprising:
a base substrate;
an anode metal layer disposed on one surface of the base substrate and comprising a plurality of anodes;
a pixel definition layer disposed on a surface of the anode metal layer facing away from the base substrate;
wherein the pixel definition layer comprises:
a plurality of pixel openings corresponding to the anodes, at least part of an anode of the plurality of anodes being exposed through a pixel opening corresponding to the anode;
a plurality of first protrusions disposed on a surface of the pixel definition layer facing away from the base substrate, each of the plurality of first protrusions being located between two adjacent pixel openings in a first direction, the first direction being parallel to a plane where the base substrate is located;
wherein each of the plurality of first protrusions has a first orthogonal projection on the plane where the base substrate is located, and each of the plurality of pixel openings has a second orthogonal projection on the plane; in the first direction, the first orthogonal projection is parallel to two adjacent second orthogonal projections.

2. The display panel according to claim 1, wherein in the first direction, minimum distances between the first protrusion and two pixel openings adjacent to the first protrusion in the first direction are both greater than 3 μm.

3. The display panel according to claim 1, wherein in the first direction, minimum distances between the first protrusion and two pixel openings adjacent to the first protrusion are equal.

4. The display panel according to claim 1, wherein the first orthogonal projection is in a shape of a rectangle, and a long side of the rectangle is perpendicular to the first direction.

5. The display panel according to claim 4, wherein an aspect ratio of the rectangle is not greater than 1.5.

6. The display panel according to claim 1, wherein an area of the first protrusions accounts for no less than 6% of a display region of the display panel.

7. The display panel according to claim 1, further comprising a pixel circuit, wherein the anode is connected to the pixel circuit through a conductive hole;
the conductive hole is located between two adjacent pixel openings in a second direction; wherein the second direction is parallel to the plane where the base substrate is located and intersects the first direction.

8. The display panel according to claim 7, wherein in a direction parallel to the plane where the base substrate is located, a distance between the first protrusion and the conductive hole adjacent to the first protrusion is greater than 3 μm.

9. The display panel according to claim 1, wherein the plurality of pixel openings comprise a first pixel opening and a second pixel opening adjacent in the first direction; the first pixel opening corresponds to a first sub-pixel, and the second pixel opening corresponds to a second sub-pixel; the first sub-pixel and the second sub-pixel have different light-emitting colors;
the pixel definition layer between the first pixel opening and the second pixel opening comprises the first protrusion; the second orthogonal projection corresponding to the first pixel opening has a first side, the second orthogonal projection corresponding to the second pixel opening has a second side, and the first side and the second side are parallel and opposite in the first direction; the first orthogonal projection corresponding to the first protrusion is located between the first side and the second side, and the first orthogonal projection has a third side parallel and opposite to the first side and a fourth side parallel and opposite to the second side; a length of the first side is A1, a length of the second side is A2, a length of the third side is B1, and a length of the fourth side is B2;
wherein A1>A2 and B1>B2.

10. The display panel according to claim 9, wherein
$$\frac{{A}_{1}}{{A}_{2}} = {K}_{1} \frac{{B}_{1}}{{B}_{2}} ,$$
wherein K1 is a set positive constant.

11. The display panel according to claim 1, wherein the plurality of pixel openings comprise a first pixel opening and a second pixel opening adjacent in the first direction; the first pixel opening corresponds to a first sub-pixel, and the second pixel opening corresponds to a second sub-pixel; the first sub-pixel and the second sub-pixel have different light-emitting colors;
the pixel definition layer between the first pixel opening and the second pixel opening comprises the first protrusion; the second orthogonal projection corresponding to the first pixel opening has a first side, the second orthogonal projection corresponding to the second pixel opening has a second side, and the first side and the second side are parallel and opposite in the first direction; the first orthogonal projection corresponding to the first protrusion is located between the first side and the second side; a distance between the first orthogonal projection and the first side is D1, and a distance between the first orthogonal projection and the second side is D2; a length of the first side is A1, and a length of the second side is A2;
wherein A1>A2 and D1>D2.

12. The display panel according to claim 11, wherein
$$\frac{{A}_{1}}{{A}_{2}} = {K}_{2} \frac{{D}_{1}}{{D}_{2}} ,$$
wherein K2 is a set positive constant.

13. The display panel according to claim 1, wherein the pixel definition layer further comprises second protrusions, each of the second protrusions is located between two adjacent pixel openings in a second direction, the second direction is parallel to the plane where the base substrate is located and intersecting the first direction.

14. The display panel according to claim 13, wherein each of the second protrusions has a third orthogonal projection on the plane where the base substrate is located; and
wherein the first orthogonal projection and the third orthogonal projection are congruent geometric figures, or wherein the first orthogonal projection and the third orthogonal projection are similar geometric figures and an area of the third orthogonal projection is larger than an area of the first orthogonal projection.

15. The display panel according to claim 14, wherein each of the second protrusions has a third orthogonal projection on the plane where the base substrate is located; the first orthogonal projection and the third orthogonal projection are both rectangular; a minimum included angle between a long side of the first orthogonal projection and a long side of the third orthogonal projection is 45°.

16. The display panel according to claim 13, wherein each of the second protrusions has a third orthogonal projection on the plane where the base substrate is located; a geometry of the first orthogonal projection is not similar to a geometry of the third orthogonal projection.

17. The display panel according to claim 1, wherein a sidewall angle of the first protrusion and a sidewall angle of the pixel opening are both 10° to 30°.

18. The display panel according to claim 17, wherein the sidewall angle of the pixel opening is greater than the sidewall angle of the first protrusion.

19. An electronic device, comprising a display panel, wherein the display panel comprises:
a base substrate;
an anode metal layer disposed on one surface of the base substrate and comprising a plurality of anodes;
a pixel definition layer disposed on a surface of the anode metal layer facing away from the base substrate;
wherein the pixel definition layer comprises:
a plurality of pixel openings corresponding to the anodes, at least part of an anode of the plurality of anodes being exposed through a pixel opening corresponding to the anode;
a plurality of first protrusions disposed on a surface of the pixel definition layer facing away from the base substrate, each of the plurality of first protrusions being located between two adjacent pixel openings in a first direction, the first direction being parallel to a plane where the base substrate is located;
wherein each of the plurality of first protrusions has a first orthogonal projection on the plane where the base substrate is located, and each of the plurality of pixel openings has a second orthogonal projection on the plane; in the first direction, the first orthogonal projection is parallel to two adjacent second orthogonal projections.

20. A manufacturing method of a display panel, comprising:
providing a base substrate;
forming a patterned anode metal layer on a surface of the base substrate, the anode metal layer comprising a plurality of anodes;
forming an initial pixel definition layer on the surface of the base substrate on which the plurality of anodes are formed;
forming a pixel definition layer with a desired pattern structure in the initial pixel definition layer by using a half-tone mask,
wherein the pixel definition layer comprises:
a plurality of pixel openings in one-to-one correspondence with the anodes, wherein at least part of an anode of the plurality of anodes is exposed through a pixel opening corresponding to the anode;
a plurality of first protrusions disposed on a surface of the pixel definition layer facing away from the base substrate, wherein each of the plurality of first protrusions is located between two adjacent pixel openings in a first direction, the first direction is parallel to a plane where the base substrate is located;
wherein each of the first protrusions has a first orthogonal projection on the plane where the base substrate is located, and each of the pixel openings has a second orthogonal projection on the plane; in the first direction, the first orthogonal projection is parallel to two adjacent second orthogonal projections.
